(19) United States
(12) Patent Application Publication
(10) Pub. No.: US 2025/0096187 A1
(43) Pub. Date: Mar. 20, 2025

(54) SEMICONDUCTOR MODULE

(71) Applicant: FUJI ELECTRIC CO., LTD., Kawasaki-shi (JP)

(72) Inventor: Yushi SATO, Matsumoto-city (JP)

(73) Assignee: FUJI ELECTRIC CO., LTD., Kawasaki-shi (JP)

(21) Appl. No.: 18/816,812

(22) Filed: Aug. 27, 2024

(30) Foreign Application Priority Data
Sep. 15, 2023 (JP) 2023-150428

(51) Int. Cl. H01L 23/00; H01L 23/367; H01L 25/065; H05K 1/02; H05K 1/18

(52) U.S. Cl. CPC H01L 24/40; H01L 23/367; H01L 24/29; H01L 24/32; H01L 24/37; H01L 24/73; H01L 25/0655; H05K 1/0203; H05K 1/181; H01L 2224/29139; H01L 2224/29147; H01L 2224/32227; H01L 2224/32238; H01L 2224/3701; H01L 2224/40229; H01L 2224/40499; H01L 2224/73263; H01L 2924/182; H05K 2201/066

(57) ABSTRACT

A semiconductor module includes an insulated circuit board including wiring boards each having a thickness between 600 and 900 μm; a wide-gap semiconductor chip disposed on a wiring board via a first bonding material and having a thickness between 50 and 120 μm; and a conductive member including a first bonding part, a beam part, and a second bonding part. The first bonding part is connected to the semiconductor chip via a second bonding material, and has a thickness between 0.1 and 0.8 mm and an area between 25 and 60% of the area of the semiconductor chip in plan view. The beam part extends continuously from the first bonding part via a first bent part. The second bonding part extends continuously from the beam part via a second bent part and is connected to a different wiring board adjacent to the wiring board with the semiconductor chip thereon.

### CROSS-REFERENCE TO RELATED APPLICATION

This application is based upon and claims the benefit of priority of the prior Japanese Patent Application No. 2023-150428, filed on Sep. 15, 2023, the entire contents of which are incorporated herein by reference.

### BACKGROUND OF THE INVENTION

### 1. Field of the Invention

The embodiment discussed herein relates to a semiconductor module.

### 2. Background of the Related Art

In a semiconductor module, when an overcurrent flows between the drain and the source of a semiconductor element, the voltage applied between the gate and the source is reduced by parasitic inductance in connecting members and a conductive layer (see, for example, International Publication Pamphlet No. WO 2021/010210). An intermediate plate is provided in solder sandwiched between an electrode substrate and a semiconductor chip, and the proof stress of the intermediate plate is higher than that of the electrode substrate and that of the solder within an operating temperature range of a semiconductor device (see, for example, International Publication Pamphlet No. WO 2018/020640).

A thick film electrode is formed for each of front-surface and rear-surface electrodes of a semiconductor element to thereby make the electrodes of the semiconductor element thicker (see, for example, International Publication Pamphlet No. WO 2018/163599). A front surface electrode provided on the surface of a semiconductor substrate includes a first metal electrode and a second metal electrode formed on the first metal electrode and having a roughened surface, and wires are bonded to the second metal electrode (see, for example, Japanese Laid-open Patent Publication No. 2017-005100). A wiring member is bonded with a bonding layer made of an Ag sintered material to transfer heat generated in a semiconductor chip to the wiring member (see, for example, Japanese Laid-open Patent Publication No. 2018-026417).

### SUMMARY OF THE INVENTION

According to an aspect, there is provided a semiconductor module including an insulated circuit board including an insulating plate, a plurality of circuit pattern layers each disposed on a top surface of the insulating plate and each having a thickness in a range of 600 μm to 900 μm, and a heat dissipation plate disposed on a bottom surface of the insulating plate; a wide-gap semiconductor chip disposed on a top surface of one of the plurality of circuit pattern layers via a first bonding material and having a thickness in a range of 50 μm to 120 μm; and a conductive member including a first bonding part, a first bent part, a beam part extending continuously from the first bonding part via the first bent part, a second bent part and a second bonding part extending continuously from the beam part via the second bent part, wherein the first bonding part is connected to a top surface of the wide-gap semiconductor chip via a second bonding material, having a thickness in a range of 0.1 mm to 0.8 mm, and having an area in a range of 25% to 60% of an area of the top surface of the wide-gap semiconductor chip in a plan view of the semiconductor module, and the second bonding part is connected to a different one of the plurality of circuit pattern layers, adjacent to the one of the plurality of circuit pattern layers having the wide-gap semiconductor chip disposed thereon.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device;

FIG. 2 is a lateral view of the semiconductor device;

FIG. 3 is a cross-sectional view of the semiconductor device;

FIG. 4 is a back view of the semiconductor device;

FIG. 5 illustrates a relationship between active region volume and short circuit withstand time of a semiconductor chip;

FIG. 6 is a plan view of a semiconductor unit included in a semiconductor module;

FIG. 7 is a cross-sectional view of the semiconductor unit included in the semiconductor module;

FIGS. 8A and 8B illustrate an example of a configuration of a first bonding part of a lead frame, with FIG. 8A depicting thickness of the first bonding part and FIG. 8B depicting a bonding area of the first bonding part;

FIG. 9 illustrates an example of height of the lead frame;

FIG. 10 illustrates a difference in width of bent parts of the lead frame; and

FIG. 11 illustrates an example of an effect of reducing thermal resistance by lead frame wiring.

### DETAILED DESCRIPTION OF THE INVENTION

An embodiment will be described below with reference to the accompanying drawings. Note that in the following the terms “front surface” and “top face” refer to the X-Y plane facing upward (the +Z direction) in a semiconductor device 1 of the drawings. Similarly, the term “upper” refers to the upward direction (the +Z direction) of the illustrated semiconductor device 1. On the other hand, the terms “rear surface” and “bottom face” refer to the X-Y plane facing downward (the −Z direction) in the illustrated semiconductor device 1. Similarly, the term “lower” refers to the downward direction (the −Z direction) of the illustrated semiconductor device 1. These terms have the same orientational relationships in other drawings if needed. “High” in position refers to an upper position (in the +Z direction) in the illustrated semiconductor device 1. On the other hand, “low” in position refers to a lower position (in the −Z direction) in the illustrated semiconductor device 1. The terms “front surface”, “top face”, and “upper”; the terms “rear surface”, “bottom face”, and “lower”; and the term “lateral face” are simply expedient expressions to specify relative positional relationships, and are not intended to limit the technical ideas of the embodiment described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of no more than ±10%. In addition, the terms “perpendicular”, “orthogonal”, and “parallel” may also include substantially perpendicular, substantially orthogonal, and substantially parallel, as appropriate, which may include a margin of error of ±10° or less.

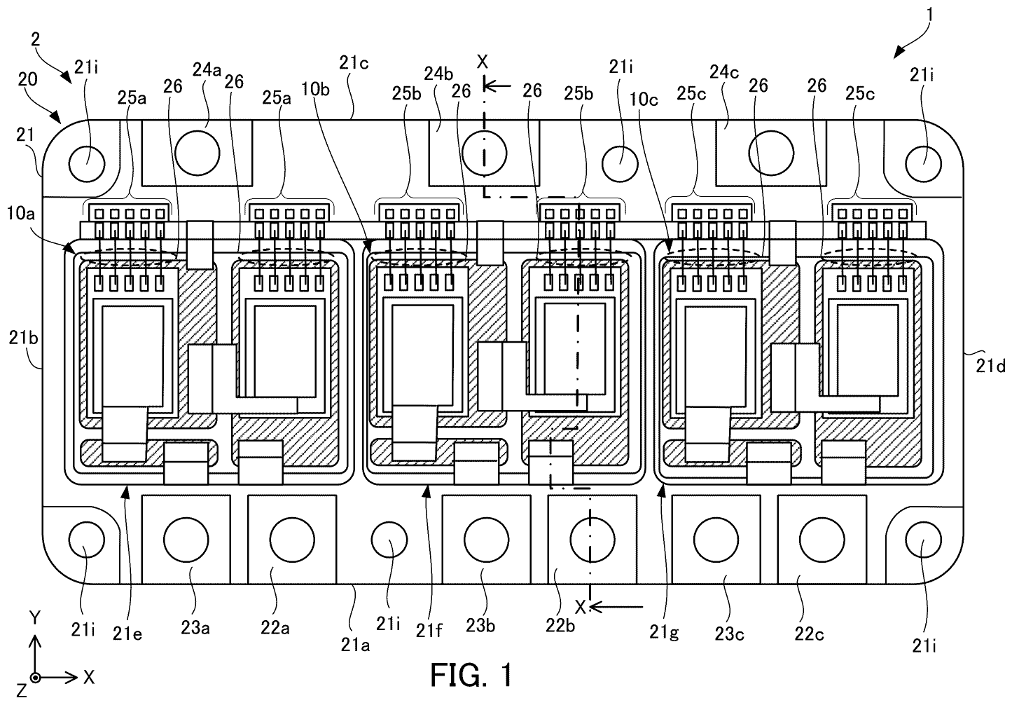

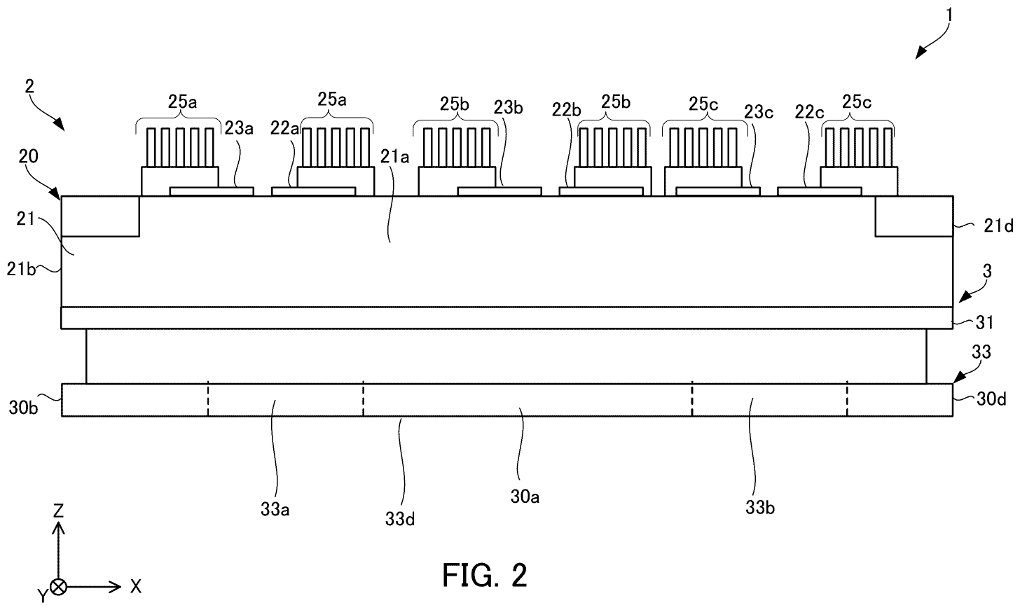

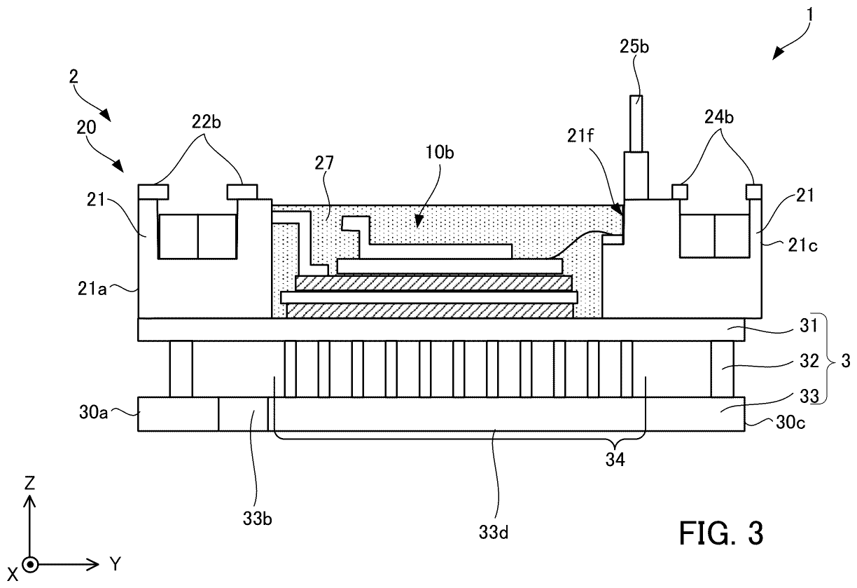

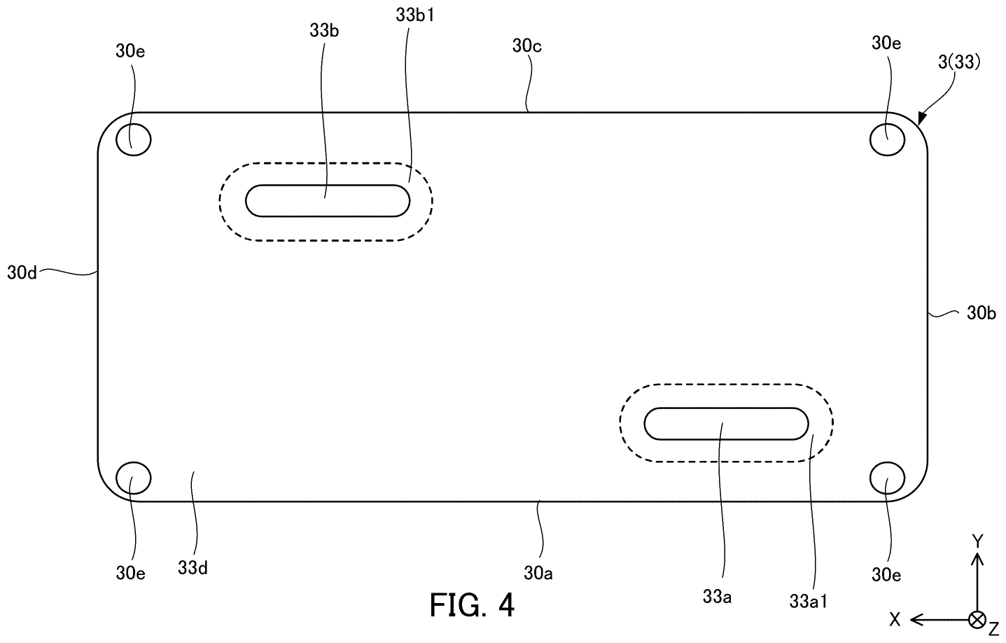

The semiconductor device 1 is described with reference to FIGS. 1 to 4. FIG. 1 is a plan view of the semiconductor device. FIG. 2 is a lateral view of the semiconductor device. FIG. 3 is a cross-sectional view of the semiconductor device. FIG. 4 is a back view of the semiconductor device. Note that FIG. 1 omits the illustration of a sealing member. The lateral view of FIG. 2 depicts an X-Z plane of FIG. 1, viewed in the direction of the Y-axis. The cross-sectional view of FIG. 3 is taken along dashed-dotted line X-X of FIG. 1. The back view of FIG. 4 is obtained by rotating the semiconductor device 1 of FIG. 1 around a center line passing through the centers of lateral walls 21a and 21c.

The semiconductor device 1 includes a semiconductor module 2 and a cooling device 3. The semiconductor module 2 includes semiconductor units 10a, 10b, and 10c and a case 20 for housing the semiconductor units 10a, 10b, and 10c. The semiconductor units 10a, 10b, and 10c each include semiconductor chips (wide-gap semiconductor chips), and are arranged in a line on the cooling device 3. The case 20 is installed on the cooling device 3 such that the semiconductor units 10a, 10b, and 10c are housed in the case 20. The semiconductor units 10a, 10b, and 10c housed in the case 20 are sealed with a sealing member 27. Note that the semiconductor units 10a, 10b, and 10c all have the same configuration. The semiconductor units 10a, 10b, and 10c will simply be called “semiconductor units 10” if there is no need to distinguish between them. Details of the semiconductor units 10 will be described later.

The case 20 includes an outer frame 21; first connection terminals 22a, 22b, and 22c; second connection terminals 23a, 23b, and 23c; a U-phase output terminal 24a; a V-phase output terminal 24b; a W-phase output terminal 24c; and control terminals 25a, 25b, and 25c.

The outer frame 21 has a rectangular shape in plan view and is surrounded on all four sides by the lateral walls 21a, 21b, 21c, and 21d. Note that the lateral walls 21a and 21c are the long sides of the outer frame 21 while the lateral walls 21b and 21d are the short sides of the outer frame 21. The corners where two adjacent lateral walls 21a, 21b, 21c, and 21d meet do not necessarily have a right angle in plan view. Each of the corners may be R-chamfered, for example, as illustrated in FIG. 1. The rear surface of the outer frame 21 (the lateral walls 21a, 21b, 21c, and 21d) may lie in the same plane and be parallel to the X-Y plane.

At each corner of the front surface of the outer frame 21, a mounting hole 21i is formed through the outer frame 21. Note that the mounting holes 21i may be formed below the front surface of the outer frame 21. Furthermore, yet another mounting hole 21i penetrating the outer frame 21 may be formed on each of the lateral wall 21a and 21c sides of the outer frame 21.

The outer frame 21 includes unit housing spaces 21e, 21f, and 21g positioned at the center of the front surface in the ±Y direction, along the lateral walls 21a and 21c (stretching in the ±X direction). In plan view, each of the unit housing spaces 21e, 21f, and 21g is open and demarcated in the shape of a rectangle on the front surface of the outer frame 21. The semiconductor units 10a, 10b, and 10c are housed in the unit housing spaces 21e, 21f, and 21g, respectively. Therefore, the size of the unit housing spaces 21e, 21f, and 21g may be such that the semiconductor units 10a, 10b, and 10c are stored therein.

In plan view, the outer frame 21 has, on the lateral wall 21a side of the front surface, the first connection terminals 22a, 22b, and 22c and the second connection terminals 23a, 23b, and 23c aligned along the lateral wall 21a (in the ±X direction). The first connection terminals 22a, 22b, and 22c may be positive input terminals (P terminals). The second connection terminals 23a, 23b, and 23c may be negative input terminals (N terminals).

In addition, the outer frame 21 has, on the lateral wall 21c side of the front surface, the U-phase output terminal 24a, the V-phase output terminal 24b, and the W-phase output terminal 24c aligned along the lateral wall 21c (in the ±X direction). At this time, the U-phase output terminal 24a is located across the unit housing space 21e from the first connection terminal 22a and the second connection terminal 23a. Similarly, the V-phase output terminal 24b is located across the unit housing space 21f from the first connection terminal 22b and the second connection terminal 23b. The W-phase output terminal 24c is located across the unit housing space 21g from the first connection terminal 22c and the second connection terminal 23c.

Note that the front surface of the outer frame 21 houses nuts below (in the −Z direction) the openings of the first connection terminals 22a, 22b, and 22c and the second connection terminals 23a, 23b, and 23c in such a manner as to oppose these openings. The front surface of the outer frame 21 also houses nuts below (in the −Z direction) the openings of the U-phase output terminal 24a, the V-phase output terminal 24b, and the W-phase output terminal 24c in such a manner as to oppose these openings. Further, the control terminals 25a, 25b, and 25c are positioned on the front surface of the outer frame 21, in plan view, between the unit housing spaces 21e, 21f, and 21g and the U-phase output terminal 24a, the V-phase output terminal 24b, and the W-phase output terminal 24c, respectively. Here, each set of the control terminals 25a, 25b, and 25c may be divided into two groups for the individual unit housing spaces 21e, 21f, and 21g, as depicted in FIG. 1.

The aforementioned outer frame 21 including the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c is integrally formed by injection molding using a thermoplastic resin. In this manner, the case 20 is configured. As the thermoplastic resin, any of the following may be used: a poly phenylene sulfide resin; a polybutylene terephthalate resin; a polybutylene succinate resin; a polyamide resin; and an acrylonitrile butadiene styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c are made of a metal with excellent electrical conductivity. Such a metal is, for example, copper, aluminum, or an alloy containing at least one of these as a major component. Plating may be applied to coat the surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c. In this case, a material used for plating is, for example, nickel, a nickel-phosphorus alloy, or a nickel-boron alloy. The plated first connection terminals 22a, 22b, and 22c, second connection terminals 23a, 23b, and 23c, U-phase output terminal 24a, V-phase output terminal 24b, W-phase output terminal 24c, and control terminals 25a, 25b, and 25c exhibit improved corrosion resistance. Note that, hereinafter, the first connection terminals 22a, 22b, and 22c will be referred to as the first connection terminals 22 unless otherwise distinguished. Similarly, the second connection terminals 23a, 23b, and 23c will be referred to as the second connection terminals 23, and the U-phase output terminal 24a, the V-phase output terminal 24b, and the W-phase output terminal 24c will be referred to as the output terminals 24.

The sealing member 27 may be a thermosetting resin. The thermosetting resin is, for example, epoxy resin, phenolic resin, maleimide resin, or polyester resin; however, epoxy resin may be preferred. A filler may be added to the sealing member 27. The filler may be ceramic with insulation properties and high thermal conductivity. Alternatively, the sealing member 27 may be a silicone gel.

The cooling device 3 includes an inlet 33a through which a refrigerant flows into the inside, and an outlet 33b through which the refrigerant having circulated inside flows out to the outside. The cooling device 3 cools the semiconductor units 10 by discharging heat from the semiconductor units 10 via the refrigerant. Examples of the refrigerant used here include water, an antifreeze solution (ethylene glycol aqueous solution), and a long-life coolant. The cooling device 3 may include a pump and a heat dissipation device (radiator). The pump makes the refrigerant circulate by causing it to flow into the inlet 33a of the cooling device 3 and causing the refrigerant that has flowed out from the outlet 33b to flow back into the inlet 33a again. The heat dissipation device receives the refrigerant flowing out from the cooling device 3 and externally radiates the heat of the refrigerant, to which the heat of the semiconductor units 10 has been conducted.

The above-described cooling device 3 includes a top plate 31, a lateral wall 32 connected in a circular pattern to the rear surface of the top plate 31, and a cooling bottom plate 33 opposing the top plate 31 and connected to the rear surface of the lateral wall 32. The top plate 31 has a rectangular shape, surrounded on the four sides by long sides and short sides in plan view, and has a fastener hole 30e in each of the four corners. Each corner of the top plate 31 may be R-chamfered in plan view. On the front surface of the top plate 31, the semiconductor units 10a, 10b, and 10c are bonded along the ±X direction. The lateral wall 32 is formed continuously in a circular pattern on the rear surface of the top plate 31. Multiple dissipation fins 34 are provided, on the rear surface of the top plate 31, in a region corresponding to the region where the semiconductor units 10a, 10b, and 10c are disposed.

The cooling bottom plate 33 has a flat plate-like shape, and has the same shape as the top plate 31 in plan view. That is, the cooling bottom plate 33 has a rectangular shape surrounded on all four sides by long sides 30a and 30c and short sides 30b and 30d in plan view, and has, in the four corners, the fastener holes 30e corresponding to those of the top plate 31. In addition, each corner of the cooling bottom plate 33 may also be R-chamfered. The cooling bottom plate 33 has a front surface and a bottom surface 33d that are parallel to each other. The bottom surface 33d of the cooling bottom plate 33 is flat with no difference in level and lies in the same plane. Furthermore, the bottom surface 33d of the cooling bottom plate 33 and the front surface of the top plate 31 may also be parallel to each other.

The bottom surface 33d of the cooling bottom plate 33 is provided with the inlet 33a and the outlet 33b through which the refrigerant flows in and out, respectively. Note that sealing areas 33a1 and 33b1 are provided around the inlet 33a and the outlet 33b on the bottom surface 33d of the cooling bottom plate 33, to surround the inlet 33a and the outlet 33b, respectively. Water distribution heads are attached to the inlet 33a and the outlet 33b via ring-shaped rubber packings in the sealing areas 33a1 and 33b1 surrounding the inlet 33a and the outlet 33b. A water distribution pipe connected to the pump is attached to each of the water distribution heads.

Next described is a reduction in short circuit withstand time associated with miniaturization of a semiconductor chip. As for semiconductor modules, semiconductor chips are becoming smaller with miniaturization of the modules. However, the reduction in the size of the semiconductor chips leads to the problem of reduced chip active region volume. The chip active region volume is an effective region through which current flows.

The reduced chip active region volume causes a reduction in heat capacity, and also leads to an increase of thermal resistance due to reduced chip surface area. Therefore, in order to avoid performance degradation of the semiconductor module, it is important to take measures to maintain the temperature of bonding parts equal to or below a specified value during operation and to improve heat dissipation from the semiconductor chips.

On the other hand, when a semiconductor chip is short-circuited, a large current of several thousand amperes (A) flows while a high voltage is applied. This places a large stress on the semiconductor chip, which will be destroyed if the semiconductor chip continues to be left in this state. The time that a semiconductor chip is able to withstand a short circuit without destruction is defined as the short circuit withstand time.

One of the causes of short-circuit failures is that thermal runaway occurs due to abnormal leakage current induced after interruption of the short-circuit current, which rapidly increases the internal temperature of the semiconductor chip. In operating conditions where such short-circuit failures occur, the short circuit withstand time of semiconductor chips decreases as miniaturization (thinning) of the semiconductor chips progresses.

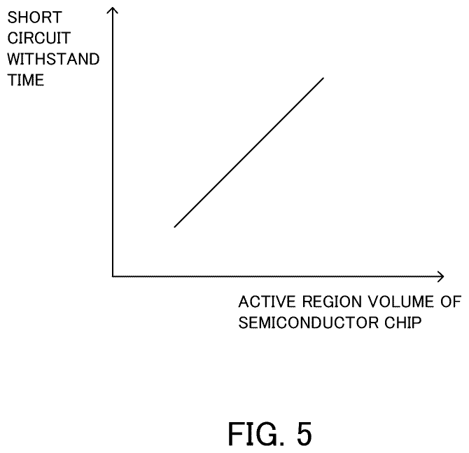

FIG. 5 illustrates the relationship between the active region volume and the short circuit withstand time of a semiconductor chip. The vertical axis represents the short circuit withstand time while the horizontal axis represents the active region volume. The active region volume of a semiconductor chip is proportional to the short circuit withstand time thereof, and the short circuit withstand time is reduced more as the active region volume becomes smaller.

In a thinned semiconductor chip, the active region volume is reduced, which in turn reduces heat capacity. As a result, the chip temperature readily increases in a thermal runaway event after interruption of the short-circuit current. This leads to a reduction of the short circuit withstand time. In view of the above, this embodiment improves heat dissipation by increasing the bonding area between a semiconductor chip and a wire even if the thinned semiconductor chip has reduced heat capacity. This suppresses the temperature increase, thereby improving the short circuit withstand time.

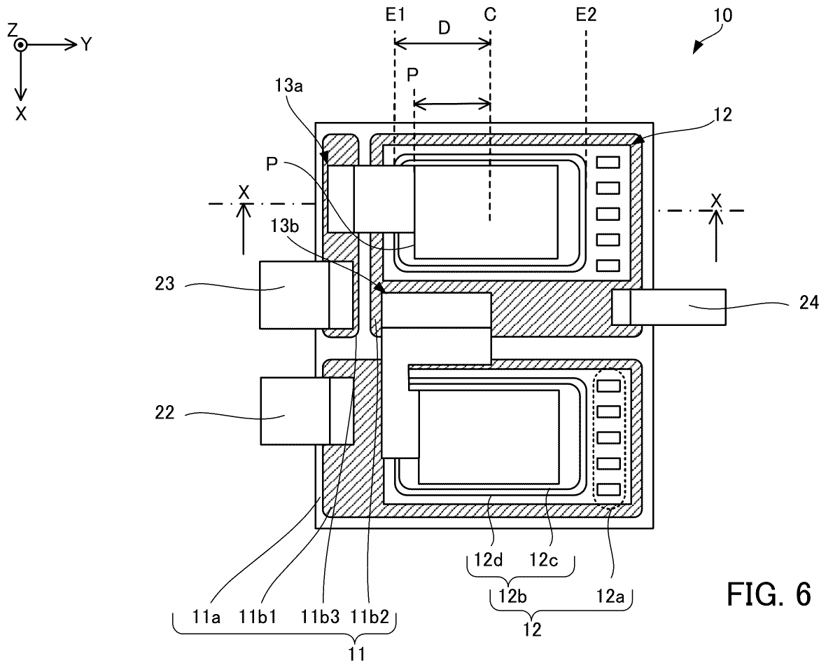

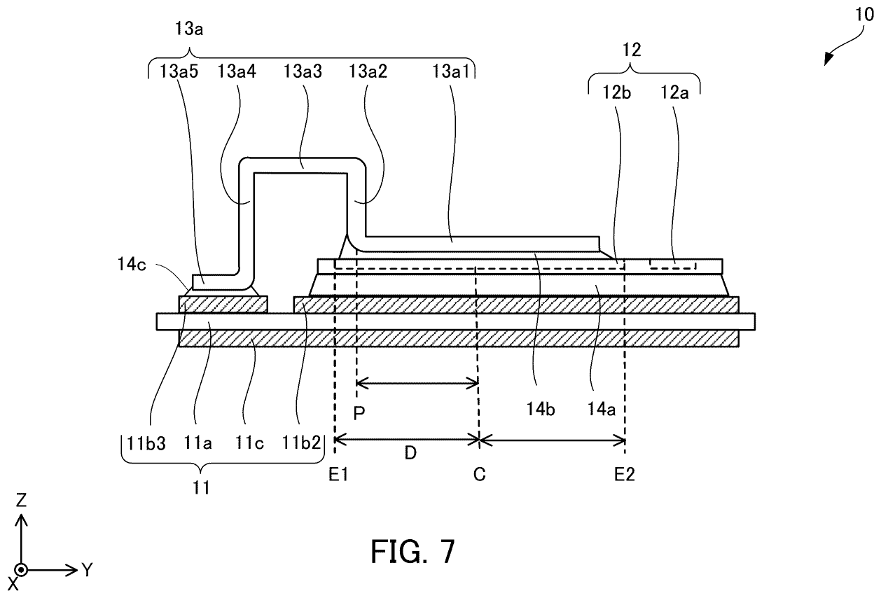

Next described is the semiconductor module 2 of this embodiment, with improved short circuit withstand time. FIG. 6 is a plan view of a semiconductor unit included in the semiconductor module. FIG. 7 is a cross-sectional view of the semiconductor unit included in the semiconductor module. Note that FIG. 6 depicts a case where the first connection terminal 22, the second connection terminal 23, and the output terminal 24 included in the case 20 are connected to the semiconductor unit 10. The cross-sectional view of FIG. 7 is taken along dashed-dotted line X-X of FIG. 6.

The semiconductor unit 10 includes an insulated circuit board 11, semiconductor chips 12, and lead frames 13a and 13b (conductive members). Each of the semiconductor chips 12 is a wide-gap semiconductor chip having a thickness of 50 μm or more and 120 μm or less, and is bonded to a wiring board 11b2 of the insulated circuit board 11 via a bonding material 14a (first bonding material). The lead frames 13a and 13b are bonded to the semiconductor chips 12 via a bonding material 14b (second bonding material).

The insulated circuit board 11 includes an insulating plate 11a, wiring boards 11b1, 11b2, and 11b3 which are circuit pattern layers, and a metal plate 11c for heat dissipation. The insulating plate 11a and the metal plate 11c have a rectangular shape in plan view. In addition, the insulating plate 11a and the metal plate 11c may have R- or C-chamfered corners. The metal plate 11c is smaller in size than the insulating plate 11a in plan view, and is thus formed within the insulating plate 11a.

The insulating plate 11a is made of a material with insulation properties and excellent thermal conductivity. The insulating plate 11a is a ceramic plate having a thickness of 200 μm or more and 400 μm or less and containing silicon nitride as a major component. Alternatively, the major component may be aluminum oxide, aluminum nitride, or silicon nitride. Further, the insulating plate 11a may be made of an insulating resin. The insulating resin here is, for example, paper phenol substrate, paper epoxy substrate, glass composite substrate, or glass epoxy substrate.

The wiring boards 11b1, 11b2, and 11b3 are formed on the front surface of the insulating plate 11a. The wiring boards 11b1, 11b2, and 11b3 have a thickness of 600 μm or more and 900 μm or less, and are made of a metal with excellent conductivity. The metal is, for example, copper, aluminum, or an alloy whose major component is at least one of these. Plating may be applied to coat the surfaces of the wiring boards 11b1, 11b2, and 11b3. In this case, a material used for plating is, for example, nickel, a nickel-phosphorus alloy, or a nickel-boron alloy. The plated wiring boards 11b1, 11b2, and 11b3 exhibit improved corrosion resistance.

The wiring board 11b1 occupies half the area of the front surface of the insulating plate 11a on the +X direction side, and spreads across the entire region from the −Y direction side to the +Y direction side. On the other hand, the wiring board 11b2 occupies half the area of the front surface of the insulating plate 11a on the −X direction side. The wiring board 11b2 extends from the +Y direction side to the −Y direction side, with a gap to the −Y direction side. The wiring board 11b3 occupies, on the front surface of the insulating plate 11a, an area surrounded by the wiring boards 11b1 and 11b2.

The above-described wiring boards 11b1, 11b2, and 11b3 are formed on the front surface of the insulating plate 11a by the following means. For example, a metal plate is formed on the front surface of the insulating plate 11a and then subjected to etching or the like, to thereby obtain the wiring boards 11b1, 11b2, and 11b3 with predetermined shapes. Alternatively, the wiring boards 11b1, 11b2, and 11b3 preliminarily cut out of a metal plate are pressure bonded to the front surface of the insulating plate 11a. Note that the wiring boards 11b1, 11b2, and 11b3 are merely an example, and appropriate changes may be made to the number of wiring boards 11b1, 11b2, and 11b3, their shapes, sizes and locations on an as-needed basis.

The metal plate 11c is formed on the rear surface of the insulating plate 11a. The metal plate 11c has rectangular shape. plate 11c in plan view is smaller than that of the insulating plate 11a, but larger than the area of the region where the wiring boards 11b1, 11b2, and 11b3 are formed. The metal plate 11c may have R- or C-chamfered corners. The metal plate 11c is smaller in size than the insulating plate 11a, and is formed on the entire surface of the insulating plate 11a except for the edges. The metal plate 11c is made of a metal with excellent thermal conductivity as a major component. The metal is, for example, copper, aluminum, or an alloy including at least one of these. Plating may be applied to coat the surface of the metal plate 11c. In this case, a material used for plating is, for example, nickel, a nickel-phosphorus alloy, or a nickel-boron alloy. The plated metal plate 11c exhibits improved corrosion resistance.

As the insulated circuit board 11 having the above-described configuration, for example, a direct copper bonding (DCB) board, an active metal brazed (AMB) board, or a resin insulating board may be used. The insulated circuit board 11 may be attached to the front surface of the top plate 31 of the cooling device 3 via a bonding material (not illustrated). This allows heat generated in the semiconductor chips 12 to be conducted to the cooling device 3 via the wiring boards 11b1 and 11b2, the insulating plate 11a, and the metal plate 11c and then radiated outwards.

The bonding materials 14a and 14b are, for example, solder, a brazing material, or metal sintered compacts. The solder used is lead-free solder. The lead-free solder contains, as a major component, an alloy containing at least two selected from tin, silver, copper, zinc, antimony, indium, and bismuth, for example. Further, the solder may include an additive, such as nickel, germanium, cobalt, or silicon. The inclusion of the additive increases wettability, brightness, and bond strength of the solder, which results in improved reliability. The brazing material contains, as a major component, at least one selected from an aluminum alloy, a titanium alloy, a magnesium alloy, a zirconium alloy, and a silicon alloy, for example. The insulated circuit board 11 may be bonded to the cooling device 3 by brazing using such a bonding material. The metal sintered compacts contain, for example, silver or a silver alloy as a major component. Alternatively, the bonding material may be a thermal interface material. The thermal interface material is an adhesive material including,, for example, an elastomer sheet, room temperature vulcanization (RTV) rubber, gel, and a phase change material. Attachment of the semiconductor units 10 to the cooling device 3 via the foregoing brazing material or thermal interface material improves heat dissipation of the semiconductor units 10.

Each of the semiconductor chips 12 includes a power device element made of silicon. The power device element may be a reverse-conducting insulated gate bipolar transistor (RC-IGBT). The RC-IGBT incorporates an IGBT, which is a switching element, and a diode element electrically connected antiparallel to the IGBT and having a function of a free wheeling diode (FWD).

The front surface of each aforementioned semiconductor chip 12 has a rectangular shape in plan view, and includes control electrodes 12a (a gate electrode) and an output electrode 12b (a source electrode functioning as a main electrode), which is an upper electrode. The thickness of the semiconductor chip 12 is 50 μm or more and 120 μm or less.

The multiple control electrodes 12a are laid out in a row, close to and along a first short side of the front surface of the semiconductor chip 12. A control signal is input to the control electrodes 12a. The output electrode 12b has a rectangular shape in plan view. Note that the positions of the lateral faces of the output electrode 12b in the longitudinal direction are denoted by positions E1 and E2, respectively.

The output electrode 12b is provided, on a second short side of the front surface of the semiconductor chip 12, adjacent to the control electrodes 12a. When the center of the output electrode 12b is defined as a center C, the center C is located in the middle of the electrode lateral faces (the positions E1 and E2). The shortest distance from the center C to the position E1, i.e., a first electrode lateral face, is distance D, for example. Similarly, the shortest distance from the center C to the position E2, i.e., a second electrode lateral face, is also the distance D.

The output electrode 12b further includes an electrode region 12c and a wiring structure part 12d. The electrode region 12c is a region at which current is output from the semiconductor chip 12. A plating layer may be formed in the electrode region 12c, and the electrode region 12c may include a gate runner. The wiring structure part 12d is provided on the top face of the output electrode 12b in such a manner as to continuously surround the outer periphery of the electrode region 12c. In addition, an input electrode (a collector electrode functioning as a main electrode), whose reference numeral is not given, is provided on the rear surface of the semiconductor chip 12.

Note that, as the semiconductor chip 12, a pair of a switching element and a diode element may be used instead of an RC-IGBT. The switching element is, for example, an IGBT or power metal oxide semiconductor field effect transistor (power MOSFET). The semiconductor chip 12 including the switching element has, on its front surface, control electrodes (a gate electrode) and an output electrode (a source or emitter electrode functioning as a main electrode), and has, on its rear surface, input electrode (a drain or collector electrode functioning as a main electrode). On the other hand, the semiconductor chip 12 including the diode element may use, for example, a Schottky barrier diode (SBD) or a P-intrinsic-N (PiN) diode as the FWD. This semiconductor chip 12 has, on its front surface, an input electrode (an anode electrode functioning as a main electrode), and has, on its rear surface, an output electrode (a cathode electrode functioning as a main electrode).

Alternatively, instead of an RC-IGBT, the semiconductor chip 12 may use a power MOSFET made of silicon carbide. The body diode of the power MOSFET may perform similar functions to the FWD of the RC-IGBT. This semiconductor chip 12 has, on its front surface, a control electrode (a gate electrode) and an output electrode (a source electrode functioning as a main electrode), and has, on its rear surface, an input electrode (a drain electrode functioning as a main electrode).

The rear surface of each semiconductor chip 12 is bonded onto the predetermined wiring board 11b2 or 11b1 via the bonding material 14a. The bonding material 14a is a sintered material containing silver or copper as a major component, and has a thickness of 10 μm or more and 300 μm or less. Alternatively, the bonding material 14a may be solder or a metal sintered compact. The solder used is lead-free solder. The lead-free solder contains, as a major component, an alloy containing at least two selected from tin, silver, copper, zinc, antimony, indium, and bismuth, for example. Further, the solder may include an additive, such as nickel, germanium, cobalt, or silicon. The inclusion of the additive increases wettability, brightness, and bond strength of the solder, which results in improved reliability. The metal used for the metal sintered compact is, for example, silver or a silver alloy.

The lead frames 13a and 13b electrically connect the semiconductor chips 12 and the wiring boards 11b2 and 11b3, to make wiring connections. The semiconductor unit 10 may be a device that serves as a single-phase inverter circuit. The lead frame 13a directly connects the output electrode 12b of the semiconductor chip 12 (on the wiring board 11b2) to the wiring board 11b3. The lead frame 13b connects the output electrode 12b of the semiconductor chip 12 (on the wiring board 11b1) to the wiring board 11b2.

The lead frame 13a includes a first bonding part (main electrode bonding part) 13a1, a first bent part 13a2, a beam part 13a3, a second bent part 13a4, and a second bonding part (wiring bonding part) 13a5.

The front surface of the first bonding part 13a1 has a rectangular shape in plan view, and is surrounded sequentially by terminal lateral faces on all four sides. The four terminal lateral faces include a terminal lateral face P corresponding to a short side of the first bonding part 13a1. The first bonding part 13a1 is bonded to the output electrode 12b via the bonding material 14b, with the terminal lateral face P facing a chip lateral face, which is the second short side of the semiconductor chip 12.

Furthermore, the terminal lateral face P of the first bonding part 13a1 is separated from the center C of the output electrode 12b toward the position E1 by 40% or more of the length of the distance D. For example, when the length between the electrode lateral faces (the positions E1 and E2) of the output electrode 12b is about 20 mm, the distance D is about 10 mm. Therefore, the terminal lateral face P of the first bonding part 13a1 is separated from the center C of the output electrode 12b by 4 mm or more toward the position E1. In addition, the terminal lateral face P of the first bonding part 13a1 may be located on the inner side (the center C side) relative to the wiring structure part 12d of the output electrode 12b.

The first bent part 13a2 is integrally bonded to the terminal lateral face P of the first bonding part 13a1, and extends upward relative to the first bonding part 13a1 from the terminal lateral face P. According to this embodiment, the first bent part 13a2 is substantially orthogonal to the first bonding part 13a1. The first bent part 13a2 has a predetermined height (in the ±Z direction). The outer side of the connection portion (corner) of the first bent part 13a2 to the first bonding part 13a1 is separated by a predetermined distance from the chip lateral face of the semiconductor chip 12, located on the electrode lateral face side at the position E1. The distance spans from the guard ring to the lead frame 13a, and is, for example, 0.4 mm or more and 1.5 mm or less. This reduces distortion occurring between the lead frame 13a and the semiconductor chip 12.

The beam part 13a3 is integrally connected to an upper end of the first bent part 13a2 in the +Z direction. The beam part 13a3 runs parallel to the front surface of the insulated circuit board 11 and extends (in the −Y direction) to the wiring board 11b3 in plan view.

The second bent part 13a4 is integrally connected to one end of the beam part 13a3, closer to the wiring board 11b3 (in the −Y direction), and extends to the wiring board 11b3 (in the −Z direction). The second bonding part 13a5 has, for example, a rectangular shape in plan view and is bonded to the wiring board 11b3. One end of the second bonding part 13a5, closer to the wiring board 11b2, and one end of the beam part 13a3, closer to the wiring board 11b3 (in the −Y direction), are integrally connected by the second bent part 13a4. In this case, the second bent part 13a4 is substantially orthogonal to the second bonding part 13a5.

Although detailed explanation is not given here, the lead frame 13b may also include a first bonding part, a first bent part, a beam part, a second bent part, and a second bonding part, as with the lead frame 13a. Similarly to the lead frame 13a, the lead frame 13b has a terminal lateral face of the first bonding part, separated from the center C of the output electrode 12b toward the position E1 by 40% or more of the length of the distance D. Also, in the lead frame 13b, the first bent part is connected to the terminal lateral face P of the first bonding part, located close to a short side of the output electrode 12b. The beam part of the lead frame 13b extends from the first bent part to the wiring board 11b2 in plan view.

The above-described semiconductor units 10 are housed in the unit housing spaces 21e, 21f, and 21g. Inner ends of the first connection terminals 22, extending into the unit housing spaces 21e, 21f, and 21g, are directly connected to the wiring boards 11b1. Inner ends of the second connection terminals 23, extending into the unit housing spaces 21e, 21f, and 21g, are directly connected to the wiring boards 11b3. Inner ends of the output terminals 24, extending into the unit housing spaces 21e, 21f, and 21g, are directly connected to the wiring boards 11b2. Note that the first connection terminals 22, the second connection terminals 23, and the output terminals 24 may be bonded to the wiring boards 11b1, 11b3, and 11b2, respectively, using the bonding material described above.

Alternatively, the first connection terminals 22, the second connection terminals 23, and the output terminals 24 may be directly bonded to the wiring boards 11b1, 11b3, and 11b2, for example, by laser or ultrasonic welding. In addition, the control electrodes 12a of the semiconductor chips 12 housed in the unit housing spaces 21e, 21f, and 21g are directly connected to the control terminals 25a, 25b, and 25c by wires 26. The wires 26 may be made of, for example, aluminum, aluminum alloy, copper, or copper alloy.

The above-described lead frames 13a and 13b are made of a metal with excellent electrical conductivity. The metal is, for example, copper, aluminum, or an alloy including at least one of these. In order to provide improved corrosion resistance, plating may be applied to coat the surfaces of the lead frames 13a and 13b. In this case, a material used for plating is, for example, nickel, a nickel-phosphorus alloy, or a nickel-boron alloy. The plated lead frames 13a and 13b exhibit improved corrosion resistance.

The bonding material 14b for bonding the first bonding part 13a1 of the lead frame 13a and the semiconductor chip 12 is lead-free solder, which has a thickness of 10 μm or more and 300 μm or less. Alternatively, the bonding material 14b may be a sintered material whose major component is silver or copper. Also in this case, the thickness of the sintered material is 10 μm or more and 300 μm or less.

The lead frames 13a and 13b may be bonded to the wiring boards 11b3 and 11b2, respectively, by a bonding material 14c. The bonding material 14c may be the aforementioned solder or sintered compact. Alternatively, the lead frames 13a and 13b may be directly bonded to the wiring boards 11b3 and 11b2, for example, by laser or ultrasonic welding. The lead frames 13a and 13b are bonded to the output electrodes 12b of the semiconductor chips 12 via the bonding material 14b. The bonding material 14b may be made of the same material as the bonding material 14a.

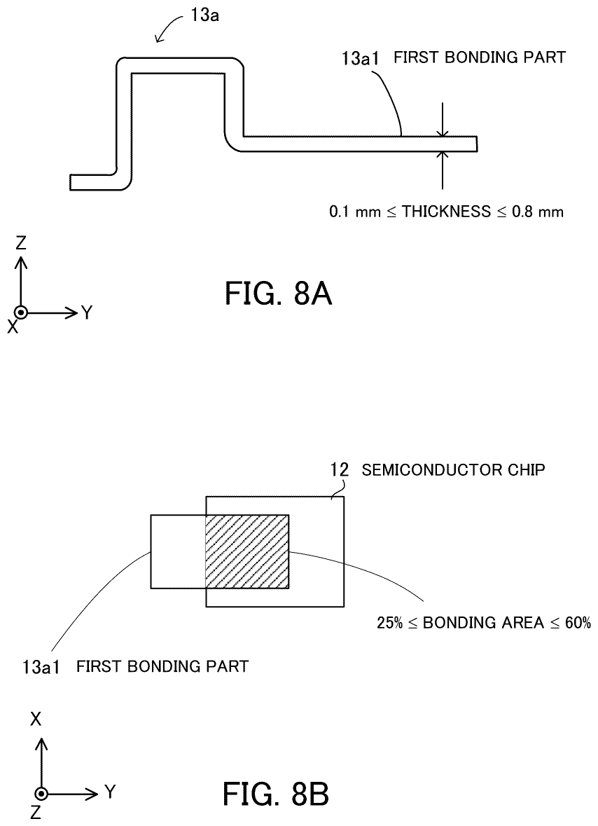

FIGS. 8A and depict example of the 8B an configuration of the first bonding part of a lead frame. FIG. 8A illustrates the thickness of the first bonding part, and FIG. 8B illustrates the bonding area of the first bonding part. The thickness of the first bonding part 13a1 is 0.1 mm or more and 0.8 mm or less. In addition, the area of the first bonding part 13a1 is 25% or more and 60% or less of the area of the top face of the semiconductor chip 12 in plan view. The reason why the thickness is set to 0.8 mm or less is because distortion may increase if the first bonding part 13a1 is thicker than that, resulting in a decrease in power cycle lifetime.

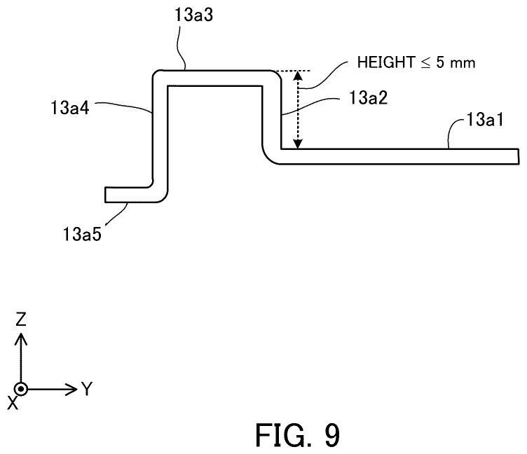

FIG. 9 illustrates an example of the height of a lead frame. The height of the lead frame 13a in the Z direction from the bonding face of the first bent part 13a2 to the top face of the beam part 13a3 is 5 mm or less. If the height exceeds 5 mm, distortion may increase, resulting in a decrease in power cycle lifetime.

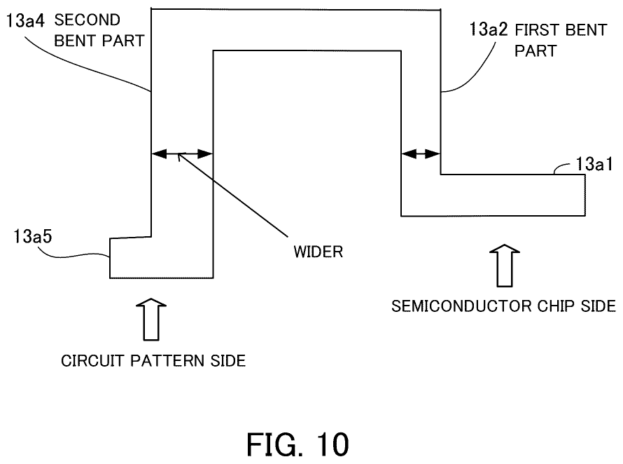

FIG. 10 illustrates a difference in width of bent parts of a lead frame. In the lead frame 13a, the second bent part 13a4 bent and extending from the second bonding part 13a5 bonded to the circuit pattern side is wider than the first bent part 13a2 bent and extending from the first bonding part 13a1 bonded to the semiconductor chip side. This configuration further improves heat dissipation of the semiconductor chip 12.

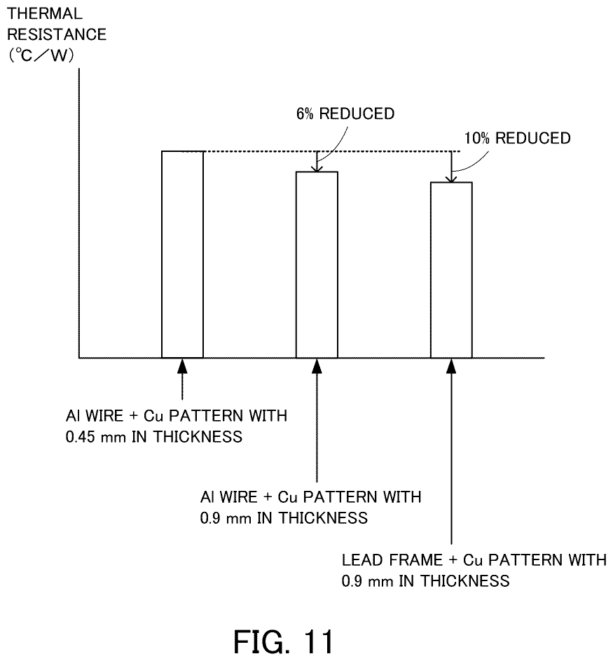

FIG. 11 illustrates an example of an effect of reducing thermal resistance by lead frame wiring. When the rear surface of the semiconductor chip 12 is bonded to the copper circuit pattern (the wiring board 11b2) and an aluminum wire is bonded to the front surface of the semiconductor chip 12, a 6% reduction in thermal resistance (° C./W) is obtained for the case with the copper circuit pattern having a thickness of 0.9 mm compared to the case with the copper circuit pattern having a thickness of 0.45 mm.

On the other hand, when the rear surface of the semiconductor chip 12 is bonded to the copper circuit pattern and a lead frame having the characteristics of the above-described embodiment is bonded to the front surface of the semiconductor chip 12, a 10% reduction in thermal resistance (° C./W) is obtained for the case with the copper circuit pattern having a thickness of 0.9 mm compared to the case where the copper circuit pattern has a thickness of 0.45 mm and an aluminum wire is used.

As has been explained above, the wiring configuration according to the embodiment is such that the lead frame including the first bonding part and the second bonding part is bonded to the front surface of the semiconductor chip. Here, the first bonding part has a thickness of 0.1 mm or more and 0.8 mm or less and has an area of 25% or more and 60% or less of the area of the top face of the semiconductor chip in plan view. The second bonding part is connected to the first bonding part and bonded to the circuit pattern layer. This configuration suppresses a decrease in heat capacity associated with miniaturization (thinning) of the semiconductor chip to thereby improve short circuit withstand time.

While, as described above, the embodiment has been exemplified, the configurations of individual portions illustrated in the embodiment may be replaced with others having the same functions. In addition, other constituent elements or processes may be added thereto. Furthermore, two or more compositions (features) of the embodiment may be combined together.

According to one aspect, it is possible to improve the short circuit withstand time of a semiconductor chip.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
an insulated circuit board including
an insulating plate,
a plurality of circuit pattern layers each disposed on a top surface of the insulating plate and each having a thickness in a range of 600 μm to 900 μm, and
a heat dissipation plate disposed on a bottom surface of the insulating plate;
a wide-gap semiconductor chip disposed on a top surface of one of the plurality of circuit pattern layers via a first bonding material and having a thickness in a range of 50 μm to 120 μm; and
a conductive member including a first bonding part, a first bent part, a beam part extending continuously from the first bonding part via the first bent part, a second bent part and a second bonding part extending continuously from the beam part via the second bent part, wherein
the first bonding part is connected to a top surface of the wide-gap semiconductor chip via a second bonding material, having a thickness in a range of 0.1 mm to 0.8 mm, and having an area in a range of 25% to 60% of an area of the top surface of the wide-gap semiconductor chip in a plan view of the semiconductor module, and
the second bonding part is connected to a different one of the plurality of circuit pattern layers, adjacent to the one of the plurality of circuit pattern layers having the wide-gap semiconductor chip disposed thereon.

2. The semiconductor module according to claim 1, wherein:
the insulating plate is a ceramic plate having a thickness in a range of 200 μm to 400 μm and containing silicon nitride as a major component.

3. The semiconductor module according to claim 1, wherein:
a height of the first bent part, which is measured from a bonding surface of the first bonding part to a top surface of the beam part, is 5 mm or less.

4. The semiconductor module according to claim 1, wherein:
the second bent part is wider than the first bent part in a direction orthogonal to a direction in which the beam part extends.

5. The semiconductor module according to claim 1, wherein:
the first bent part extends in a direction perpendicular to the first bonding part.

6. The semiconductor module according to claim 1, wherein:
the wide-gap semiconductor chip incorporates a field effect transistor and a diode electrically connected antiparallel to the field effect transistor.

7. The semiconductor module according to claim 1, wherein:
the first bonding material is a sintered material containing silver or copper as a major component.

8. The semiconductor module according to claim 7, wherein:
the first bonding material has a thickness in a range of 10 μm to 300 μm.

9. The semiconductor module according to claim 1, wherein:
the second bonding material on the wide-gap semiconductor chip is lead-free solder.

10. The semiconductor module according to claim 9, wherein:
the second bonding material has a thickness in a range of 10 μm to 300 μm.

11. The semiconductor module according to claim 1, wherein:
the second bonding material on the wide-gap semiconductor chip is a sintered material containing silver or copper as a major component.

12. The semiconductor module according to claim 11, wherein:
the second bonding material has a thickness in a range of 10 μm to 300 μm.
